(19) United States
(12) Patent Application Publication
(10) Pub. No.: US 2023/0290671 A1
(43) Pub. Date: Sep. 14, 2023

(54) WAFER CARRIER AND SYSTEM FOR AN EPITAXIAL APPARATUS

(71) Applicant: ams-OSRAM International GmbH, Regensburg (DE)

(72) Inventors: Harald DIMMELMEIER, Regensburg (DE); Harald LAUX, Regensburg (DE); Juergen OFF, Regensburg (DE)

(21) Appl. No.: 18/040,266

(22) PCT Filed: Jul. 22, 2021
(86) PCT No.: PCT/EP2021/070563

§ 371 Date: Feb. 2, 2023

(30) Foreign Application Priority Data
Aug. 3, 2020 (DE) 10 2020 120 449.3

(51) Int. Cl. H01L 21/687; H05B 3/26

(52) U.S. Cl. CPC H01L 21/68785; H05B 3/26

(57) ABSTRACT

A wafer carrier may include a first main surface suitable for receiving wafers, a second main surface arranged on a side opposite to the first main surface, and an annular depression or an elevation containing wafer carrier material in the region of the second main surface, concentric with respect to the wafer carrier.

### CROSS-REFERENCE TO RELATED APPLICATIONS

The present application is a national stage entry according to 35 U.S.C. § 371 of PCT application No.: PCT/EP2021/070563 filed on Jul. 22, 2021; which claims priority to German patent application DE 10 2020 120 449.3, filed on Aug. 3, 2020; all of which are incorporated herein by reference in their entirety and for all purposes.

### TECHNICAL FIELD

The disclosure relates to wafer carriers, in particular wafer carriers having an annular depression or an elevation containing wafer carrier material in a region of a second main surface that is concentric with respect to the wafer carrier.

### BACKGROUND

In the manufacture of semiconductor devices, epitaxial processes are typically used to deposit thin epitaxial semiconductor layers. Epitaxial growth has been found to be very temperature sensitive. For example, the composition ratio of a compound semiconductor material and hence the band gap of the compound semiconductor material strongly depend on the substrate temperature. Therefore, if temperatures vary locally, regions of different composition ratios may occur within a single wafer. Furthermore, different wafers that are processed under the same process parameters may have different composition ratios.

For this reason, efforts are being made to ensure the most uniform possible temperature inputs into the wafer in epitaxial growth processes.

### SUMMARY

It is an objective of the present disclosure to provide an improved wafer carrier and an improved system for an epitaxial apparatus.

A wafer carrier comprises a first main surface suitable for receiving wafers and a second main surface located on a side opposite to the first main surface, and an annular depression or an elevation containing wafer carrier material in the region of the second main surface, concentric with the wafer carrier.

According to embodiments, a depth of the concentric annular depression or a height of the elevation is less than 10 mm.

The wafer carrier may comprise two depressions or elevations, for example. A depth of the concentric annular depression or a height of the elevation may be greater in an edge region of the wafer carrier than in a central region of the wafer carrier. Depending on the configuration of the heater, this may also be different. For example, the depth of the concentric annular depression or the height of the elevation in an edge region of the wafer carrier may be less than or the same as in a central region of the wafer carrier.

According to further embodiments, a wafer carrier comprises a first main surface, which is suitable for receiving wafers, and a second main surface, which is located on a side opposite to the first main surface, and an annular region concentric with the wafer carrier, in which material of the wafer carrier is replaced with foreign material different from the wafer carrier material, in the region of the second main surface. According to embodiments, the wafer carrier may comprise a plurality of annular regions in which the material of the wafer carrier is replaced with foreign material different from the wafer carrier material. For example, a different foreign material may be provided in each of the different annular regions.

According to further embodiments, a wafer carrier comprises a first main surface, which is suitable for receiving wafers, and a second main surface, which is located on a side opposite to the first main surface, and an annular region concentric with the wafer carrier, which is coated with coating material having a higher absorption coefficient than the wafer carrier material, in the region of the second main surface. According to embodiments, the wafer carrier may comprise a plurality of concentric annular regions which are coated with coating material having an absorption coefficient different from that of the wafer carrier material. For example, a different coating material may be provided in each of the different annular regions.

A radially measured width of the depression or elevation is greater than 0.5 cm, for example.

According to embodiments, the or some of the different structural elements may be combined with one another in the region of the second main surface of the wafer carrier.

A system for an epitaxial apparatus comprises the wafer carrier as described above and a resistive heater arranged on the side of the second main surface.

For example, the heater may comprise two horizontal heating coils, each having concentric windings such that the heat generated by the heater varies in the radial direction.

According to embodiments, elevations on the second main surface of the wafer carrier are arranged to oppose positions of the heater having reduced heat generation. For example, a radially measured width of elevations on the second main surface of the wafer carrier is less than the radial distance between adjacent heating coils.

According to embodiments, the elevations on the second main surface of the wafer carrier are arranged to oppose positions of the heater having increased heat generation.

Furthermore, regions having reduced thermal conductivity on the second main surface of the wafer carrier may be arranged to oppose positions of the heater having increased heat generation.

For example, the regions including foreign material are positioned in such a way that regions having increased thermal conductivity on the second main surface of the wafer carrier are arranged to oppose positions of the heater having reduced heat generation.

According to embodiments, a radially measured width of regions having increased thermal conductivity on the second main surface of the wafer carrier is less than the radial distance between adjacent heating coils.

For example, the regions coated with coating material are arranged to oppose positions of the heater having reduced heat generation.

According to embodiments, a radially measured width of the regions coated with coating material on the second main surface of the wafer carrier is less than the radial distance between adjacent heating coils.

For example, one of the heating coils has a region in which a distance between adjacent windings is greater than an average distance between adjacent windings. In this case, the region coated with coating material may be arranged to oppose the region having a larger distance between adjacent windings.

### BRIEF DESCRIPTION OF THE DRAWINGS

The accompanying drawings serve to provide an understanding of non-limiting embodiments. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A schematically shows the configuration of an epitaxial apparatus, which may contain a wafer carrier according to embodiments.

FIG. 1B schematically shows a plan view of a wafer carrier.

FIG. 2 shows a plan view of a heater.

FIG. 3A shows a perspective view of a second main surface of a wafer carrier according to embodiments.

FIG. 3B shows a perspective view of a second main surface of a wafer carrier according to further embodiments.

FIG. 3C shows a perspective view of a second main surface of a wafer carrier according to further embodiments.

FIG. 4 illustrates the temperature distribution of a wafer carrier as a function of the distance from a center point of the wafer carrier.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since other exemplary embodiments may also exist and structural or logical changes may be made without departing from the scope as defined by the patent claims. In particular, elements of the exemplary embodiments described below may be combined with elements from others of the exemplary embodiments described, unless the context indicates otherwise.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical” as used in this description is intended to describe an orientation which is essentially perpendicular to the first surface of the semiconductor substrate or semiconductor body. The vertical direction may correspond, for example, to a direction of growth when layers are grown.

The wafers mentioned within the scope of the present application may be wafers on which semiconductor material may be grown epitaxially. For example, the wafers may be insulating wafers or semiconductor wafers.

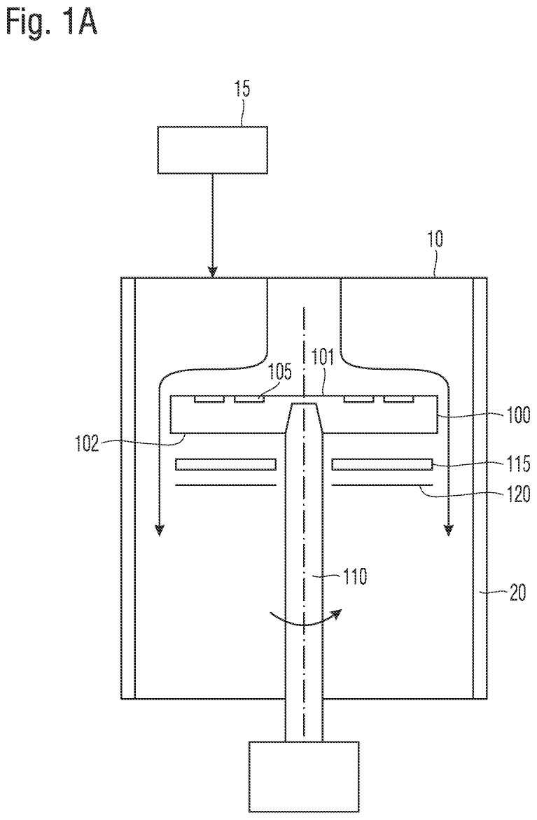

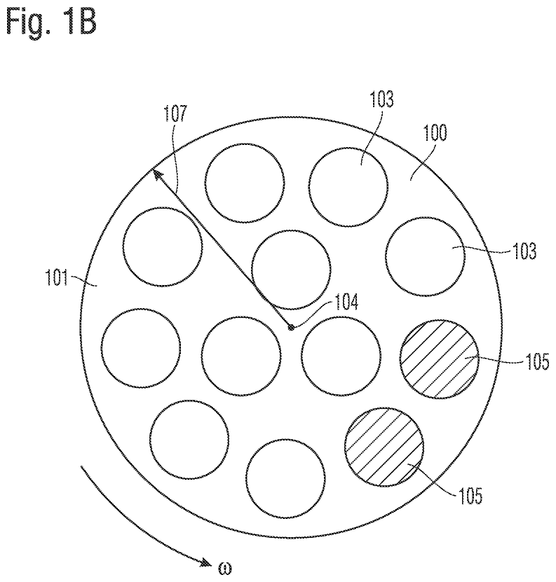

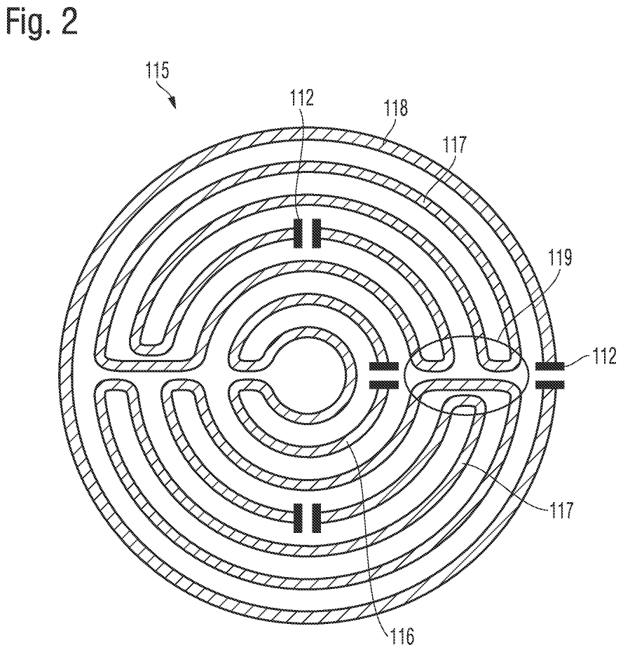

FIG. 1A shows a view of an epitaxial apparatus. A plurality of wafers 105 is arranged on a first main surface 101 of the wafer carrier 100. The exact manner in which the wafers 105 are arranged on the wafer carrier 100 will be explained in more detail with reference to FIG. 1B. The wafer carrier 100 is rotatably mounted over a rotation axis 110. The wafer carrier 100 may be rotated continuously about the rotation axis 110 using an associated motor. A heater 115 is arranged on the side of the second main surface 102 of the wafer carrier 100. The exact configuration of an example of a heater 115 will be explained in more detail with reference to FIG. 2. By impressing a current, a heating power is generated by the ohmic resistance within the heater 115. Typically, the position of the heater 115 is stationary. The heater 115 is separated from the wafer carrier rotating about the rotation axis 110 by a vertical gap filled with flushing gas.

The wafer carrier contains graphite, for example. The wafer carrier 100 may be coated with another material, for example an inert material such as SiC or the like. The wafer carrier 100 is heated through the second main surface 102 by the heater 115. The wafer carrier 100 is heated by thermal radiation and additionally by thermal conduction/convection via the flushing gas. The rotation axis 110 is actively cooled, for example. In addition, however, a vertical heating coil may also be provided in the rotation axis 110 by which the wafer carrier 100 may be further heated. The distance between the heater 115 and the wafer carrier 100 may be in the cm range, for example. For example, the distance may be less than about 5 cm or 2 cm. For example, a downwards terminating structure 120 may additionally be provided, by which the region of the apparatus that is filled with the flushing gas is delimited in a downward direction.

The epitaxial apparatus 10 further comprises a housing 20 enclosing the wafer carrier and the rotation axis 110. A gas supply device 15 may be provided in order to supply the device 10 with the gases required for epitaxial growth.

FIG. 1B shows a plan view of the first main surface 101 of the wafer carrier 100. A plurality of pockets 103 is formed in the first main surface 101 of the wafer carrier 100. The pockets 103 are of a suitable size to accommodate the individual wafers 105. The pockets 103 correspond to recesses in the first main surface 101 which are suitable for storing or holding the wafers 105. Horizontal dimension and vertical depth are selected appropriately to accommodate the wafers 105 during the epitaxial growth process. The rotation axis 110 is connected to the wafer carrier 100 such that the latter rotates about the center point 104. The radial direction 107 extends outward from the center point 104.

FIG. 2 shows a plan view of a heater 115 that may be used with wafer carriers 100 according to embodiments. The heater 115 is designed as a resistive heater. As may be seen, the heater 115 comprises a plurality of heating coils 116, 117, 118. Each of the heating coils has one or more concentric windings. In operation, the wafer carrier 100 may be arranged such that its center point 104 is located over the common center of all windings.

Due to the geometry of the coil windings, the area-specific heating power of the heater 115 is not constant. The heater has been found to include regions of significantly lower power. For example, regions having lower heating power may occur in regions between the coil windings of a heating coil. Furthermore, as illustrated in FIG. 2, the heater may comprise a plurality of separately controllable heating coils. Specific regions of the wafer carrier 100 may be heated more than others by a targeted activation of the different heating coils. However, a region having reduced heating power may occur between the separate heating coils. In addition, a region having reduced heating power may occur in the region 119 of the central heating coil 117. Region 119 corresponds to the position of the winding reversal of the central heating coil 117. As illustrated in FIG. 2, the central heating coil 117 reverses its direction at this position 119. For example, at position 119, the distance between adjacent windings may be greater than at other locations or than an average distance within heating coil 117. In addition, terminals 112 may also be provided for impressing a current into the heating coils. At these locations also, the heating power that occurs may be different from that at other locations. Furthermore, fastening elements (not shown) may be provided to fasten the heating coils. The heating power that occurs at these locations may also be different from that at other locations.

Correspondingly, the temperature of the second main surface 102 of the wafer carrier 100, into which the heat of the heater 115 is coupled, may be non-uniform. Rather, it shows dips of several Kelvin or positions of locally reduced temperatures in the gap regions of the heater 115, in particular between the individual heating coils or also in the region of position 119 of the winding reversal of the central heating coil 117. Furthermore, positions of locally reduced temperatures may occur in the region of the terminals 112.

This non-uniformity in temperature propagates vertically through the wafer carrier 100 to its first main surface 101.

Due to radial heat diffusion, the maximum temperature difference is somewhat reduced. For example, the temperature differences that result from the distance between the individual windings may be compensated for by radial heat diffusion.

Due to the remaining temperature differences, it is expected that with epitaxial growth of the active layer, for example of a blue LED, this will lead to a shift in the emission wavelength by approx. 5 nm.

In order to compensate for temperature differences that occur, it is now proposed to provide a structural element 125, 130 on the second main surface 102 of the wafer carrier, which structural element 125, 130 compensates for the differences in the surface temperature on the side of the second main surface 102. The structural element or elements 125, 130 are concentric with a center point of the wafer carrier and are annular, which means that the structural element or elements 125, 130 extend continuously along the circumference of the wafer carrier 100.

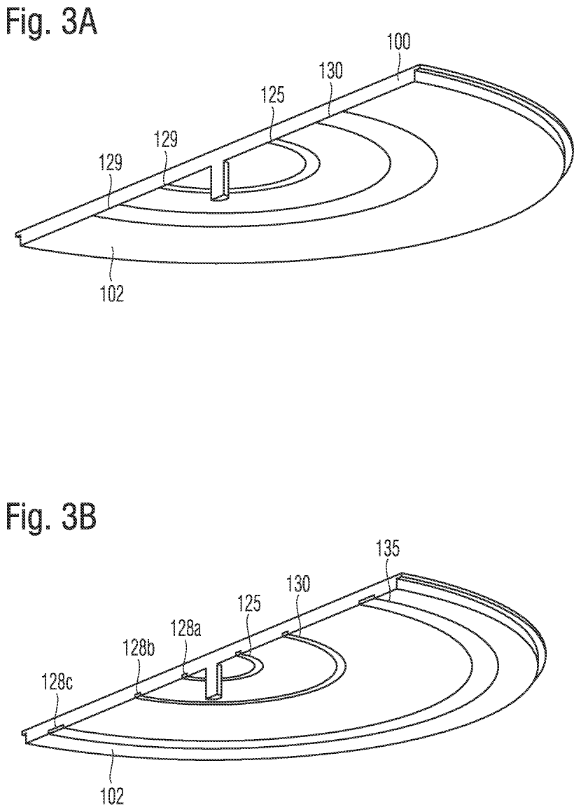

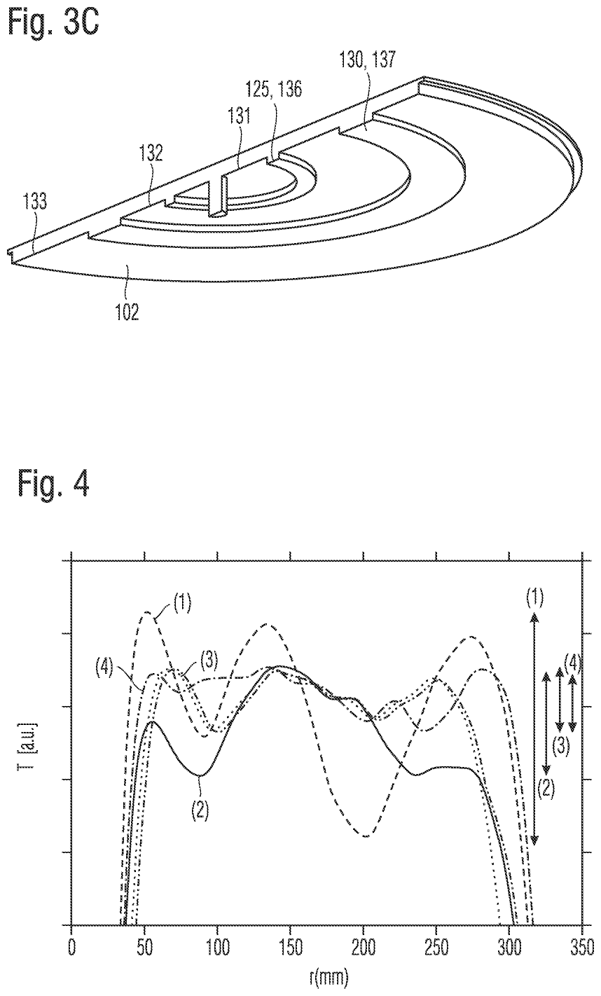

FIG. 3A shows a perspective view of a second main surface 102 of a wafer carrier 100. As illustrated in FIG. 3A, a structural element 125, 130 may be implemented by an annular surface coating. More precisely, the structural element may be implemented in the region of the second main surface 102 by an annular region concentric with the wafer carrier 100, which is coated with a coating material 129 having an increased absorption coefficient compared to the wafer carrier material.

Any material having a higher absorption coefficient for thermal radiation than the base material of the wafer carrier 100 may be used for the coating material 129. The term “base material of the wafer carrier” refers to the material of the wafer carrier in a region outside the surface coating. The base material of the wafer carrier may thus be, for example, a base material of which the wafer carrier is composed, with an associated coating.

For example, the wafer carrier may be a graphite carrier that is coated with a carbide, for example silicon carbide. In this case, the structural elements may contain or consist of TaC (tantalum carbide). Due to the increased absorption coefficient for thermal radiation, more thermal radiation may be absorbed locally at these locations.

For example, the structural elements may each be provided at positions within the second main surface 102, which may be arranged to oppose the positions of the heater 115 having reduced heat generation. For example, the structural elements may each be arranged at positions which correspond to a position between adjacent heating coils of the heater 115. According to further embodiments, one of the heating coils may also comprise a region in which a distance between adjacent windings is greater than an average distance between adjacent windings. In this case, the structural element may be arranged to oppose the region having greater distances.

This is favorable, for example, in cases in which the coating material has a higher absorption coefficient than the base material of the wafer carrier.

According to further embodiments, the material of the structural element, i.e., the coating material, may have a lower absorption coefficient than the base material of the wafer carrier 100. In this case, for example, the structural element 125, 130 may be provided in a region in which the temperature on the second main surface 102 of the wafer carrier has a local maximum. This position may correspond to a position at which the windings of the heating coils are particularly uniform.

As further illustrated in FIG. 3A, a width of the structural elements 125, 130 measured in the radial direction may vary. For example, in an outer region of the wafer carrier 100, the width of the second structural element 130 may be greater than the width of the first structural element 125 measured in the radial direction. For example, the width of the structural elements 125, 130 measured in the radial direction may depend on the distance between adjacent heating coils or the geometry of a particular heating coil. According to the embodiments shown in FIG. 3A, a changed heat input is effected by a locally increased absorption capacity.

According to embodiments, the coating material of the individual structural elements 125, 130 may differ. In particular, an absorption coefficient of the coating material may be different in each case. According to embodiments, the absorption coefficient of the coating material of the first structural element 125 may be greater than that of the base material of the wafer carrier 100. Furthermore, the absorption coefficient of the coating material of the second structural element 130 may be less than that of the base material of the wafer carrier 100.

FIG. 3B shows a view of a second main surface 102 of a wafer carrier 100, in which structural elements 125, 130, 135 are realized by replacing a part of the surface coating with a coating of a different material, a foreign material 128a, 128b, 128c. For example, the wafer carrier comprises an annular region concentric with the wafer carrier, in which material of the wafer carrier is replaced with a foreign material 128a, 128b, 128c, in the region of the second main surface 102. Unlike in the embodiments explained with reference to FIG. 3A, in wafer carriers 100 according to the embodiments illustrated in FIG. 3B, vertical heat conduction may be changed by changing the coefficients of thermal conductivity. For example, the foreign material 128 may extend to a depth of 1 mm. A material of this structural element should be mountable in the wafer carrier 100. The material should have a similar coefficient of thermal expansion as the usual coating material of the wafer carrier 100 in order to avoid detachment. For example, the foreign material 128 may have a greater or lesser coefficient of thermal conductivity.

For example, according to embodiments, the regions having a greater coefficient of thermal conductivity may each be provided at positions within the second main surface 102 that are arranged to oppose positions of the heater 115 having reduced heat generation. For example, the regions having a greater coefficient of thermal conductivity may each be arranged at positions which correspond to a position between adjacent heating coils of the heater 115. According to further embodiments, one of the heating coils may also have a region in which a distance between adjacent windings is greater than an average distance between adjacent windings. In this case, the regions having a greater coefficient of thermal conductivity may be arranged to oppose the region having greater distances. Conversely, regions having a lower coefficient of thermal conductivity may each be arranged to oppose a region in which the temperature on the second main surface 102 has a local maximum. This position may, for example, correspond to a position at which the windings of the heating coils are particularly uniform.

According to embodiments, a first foreign material 128a of a first structural element 125 may differ from a second foreign material 128b of a second structural element 130, and each may have a different coefficient of thermal conductivity. Furthermore, a third foreign material 128c of a third structural element 135 may differ from a first and/or second foreign material and may have a different coefficient of thermal conductivity. For example, a first foreign material 128a may have a greater coefficient of thermal conductivity than the wafer carrier material, and a second foreign material material 128b has a lower coefficient of thermal conductivity than the wafer carrier material or vice versa.

According to further embodiments, the second main surface 102 may be patterned by milling or elevating the material. FIG. 3C shows an example of a perspective view of the second main surface 102 of the wafer carrier. As may be seen, several structural elements 125, 130 are each implemented by webs or elevations 136, 137 of the carrier material. Correspondingly, there are regions of different vertical extensions within the wafer carrier 100. Correspondingly, the vertical distance between the heater 115 and the second main surface 102 of the wafer carrier is changed locally. Alternatively, the structural elements may also be implemented as depressions 131, 132, 133. This modifies the absorption of thermal radiation in each case. In particular, the absorption surface area of the thermal radiation is increased by the structural elements 125, 130, since the vertical component of the structural elements 125, 130 is added to the horizontal component. As a result, the heat input is increased. In this manner, spatially varying heat generation may be compensated for.

In this case, too, according to embodiments, elevations 136, 137 or depressions 131, 132, 133 may be provided at positions within the second main surface 102, respectively, which are arranged to oppose positions of the heater 115 having reduced heat generation. For example, projections 136, 137 or depressions 131, 132, 133 may each be arranged at positions corresponding to a position between adjacent heating coils of the heater 115. Also, according to further embodiments, one of the heating coils may comprise a region in which a distance between adjacent windings is greater than an average distance between adjacent windings. In this case, elevations 136, 137 or depressions 131, 132, 133 may be arranged to oppose the region having greater distances.

For example, the width of a structural element 125, 130 may in each case be less than the width of a region having a lower temperature, which region is caused by the special arrangement of the heating coils 116, 117, 118. The width of the structural element 125, 130 may be approximately half the width of the low temperature regions. For example, two to five structural elements may be used. The depth or height of the structural elements may be less than about 10 mm, for example less than 7 mm. The depth of the depressions 131, 132, 133 or the height of the elevations 136, 137 may be more than about 1 mm. This may apply, for example, in a case where the distance between the heater 115 and the second main surface 102 of the wafer carrier 100 is less than about 20 mm. The depth of the depressions 131, 132, 133 or the height of the elevations 136, 137 may vary between one another. For example, a milled depth of the depression 131 near the center of the wafer carrier 100 may be less than the milled depth of the depression 133 having a greater distance from the center of the wafer carrier 100. In this manner, the absorption surface area may be further varied. As a result, even more uniform absorption of heat radiation may be effected. According to one interpretation, the effect occurring here may mainly be attributed to more uniform absorption of the thermal radiation. In contrast, a possibly changed thermal conductivity due to the changed distance from the first main surface becomes less important.

A width of the structural elements 125, 130 according to all embodiments may, for example, be more than 0.5 cm, for example 1 to 6 cm. In this manner, the second main surface 102 of the wafer carrier 100 may be structured in a simple manner. The structural elements 125, 130 are each formed to be annular.

The structural elements 125, 130, 135 of all embodiments may be combined with one another in any manner.

As has been described, the position and characteristics of the structural elements 125, 130 are each selected in combination with the specific design of the heater 115 in order to achieve the most uniform possible temperature distribution within the wafer carrier 100. Embodiments also relate to a system comprising a wafer carrier 100 as described above and a heater 115.

FIG. 4 shows a simulation of the temperature of the wafer carrier 100 on the first main surface 101 as a function of the distance from the center point of the wafer carrier 100 for differently patterned second main surfaces 102. Curve (1) shows the temperature for a wafer carrier 100 (without pockets 103 and wafers 105 arranged therein) without a patterned second main surface 102.

As may be seen, strong variations within the temperature occur in a wafer carrier 100 without a patterned second main surface 102. If the second surface 102 is modified as illustrated in FIG. 3A, the temperature profile designated at (2) occurs. As may be seen, the variation between minimum and maximum temperature is much smaller than in curve (1). Curve (3) shows a temperature profile of the first main surface 101 with the second main surface 102 as shown in FIG. 3B being modified. As may be seen, the variation between lowest and highest temperatures is significantly lower than in curves (1) and (2). Curve (4) shows the temperature profile on the first main surface 102 of a wafer carrier 100 which is patterned according to FIG. 3C. Here, too, the variation between the highest and lowest temperatures is similarly small as in curve (3). In particular, the variation is significantly smaller than in the case of an unpatterned second main surface 102. Furthermore, the variation is smaller than with a second main surface that is coated with a material having an increased absorption coefficient compared to the wafer carrier material.

As may be seen, by using the measures described it is possible to significantly reduce the variation in the temperature of the first main surface 101 of the wafer carrier 100 and thus of the semiconductor wafer during the performance of an epitaxial process. Accordingly, a variation in the composition ratio and hence a variation in the emission wavelength of the LEDs may be remarkably reduced.

For example, according to curve (4), when providing the structural elements as described with reference to FIG. 3C, a variation of the emission wavelength of a blue LED may be reduced from approx. 5 nm to approx. 1.3 nm. The variation in emission wavelength is thus significantly lower than that which results when using a wafer carrier without a patterned second main surface 102.

By forming the structural elements described herein to be annular, that is, in a concentrical rotationally symmetrical manner, negative effects due to an imbalance may be avoided. Under certain circumstances, the moment of inertia and thus the acceleration behavior of the rotation may change slightly.

Although a specific epitaxial apparatus has been described in combination with a specific heater in the above figures, it goes without saying that the wafer carrier comprising the specific configuration of the second main surface described within the scope of the present disclosure may be combined in any epitaxial apparatus and with any heater. For example, the structure and arrangement of the elements within the epitaxial apparatus may be different from that shown in FIG. 1A. Furthermore, the wafer carrier may also be used in cases in which the heat transfer between the heater does not occur or not primarily occur through thermal radiation. For example, the heat transfer may also occur primarily through thermal conduction/convection. According to further embodiments, the heat may also be transferred through electromagnetic radiation, for example in the case of inductive heating.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 epitaxial apparatus
15 gas supply device
20 housing
100 wafer carrier
101 first main surface
102 second main surface
103 pocket
104 center point
105 wafer
107 radial direction
110 rotation axis
112 terminal
115 heater
116 inner heating coil
117 central heating coil
118 outer heating coil
119 position of the winding reversal of the central heating coil
120 downwards terminating structure
125 first structural element
128 foreign material
128a first foreign material
128b second foreign material
128c third foreign material
129 coating material
130 second structural element
131 first depression
132 second depression
133 third depression
135 third structural element
136 first elevation
137 second elevation

1. A system for an epitaxial apparatus comprising a wafer carrier; wherein the wafer carrier comprises:
a first main surface suitable for receiving wafers;
a second main surface located on a side opposite to the first main surface;
an annular depression or elevations containing wafer carrier material in the region of the second main surface, concentric with the wafer carrier; and
a resistive heater arranged on the side of the second main surface.

2. The system of claim 1, wherein a depth of the concentric annular depression or a height of the elevation is less than 10 mm.

3. A system according to claim 1, wherein the heater comprises two horizontal heating coils, each having concentric windings such that the heat generated by the heater varies in a radial direction.

4. The system of claim 3, wherein the elevations on the second main surface of the wafer carrier are arranged to oppose positions of the heater having reduced heat generation.

5. The system of claim 1, wherein a radially measured width of the elevations on the second main surface of the wafer carrier is smaller than the radial distance between adjacent heating coils.

6. The system according to claim 3, wherein the depressions on the second main surface of the wafer carrier are arranged to oppose positions of the heater having increased heat generation.

7. A system for an epitaxial apparatus comprising a wafer carrier; wherein the wafer carrier comprises:
a first main surface suitable for receiving wafers;
a second main surface located on a side opposite to the first main surface;
an annular region concentric with the wafer carrier, in which material of the wafer carrier is replaced with a foreign material different from the wafer carrier material, in a region of the second main surface; and
a resistive heater arranged on the side of the second main surface; wherein the heater comprises two horizontal heating coils, each having concentric windings such that the heat generated by the heater varies in a radial direction.

8. The system according to claim 7, further comprising
an annular depression or an elevation containing wafer carrier material in the region of the second main surface, concentric with the wafer carrier.

9. (canceled)

10. The system of claim 7, wherein the regions comprising foreign material are positioned such that regions of increased thermal conductivity on the second main surface of the wafer carrier are arranged to oppose positions of the heater having reduced heat generation or regions having reduced thermal conductivity on the second main surface of the wafer carrier are arranged to oppose positions of the heater having increased heat generation.

11. The system of claim 7, wherein a radially measured width of regions having increased thermal conductivity on the second main surface of the wafer carrier is less than the radial distance between adjacent heating coils.

12. A system for an epitaxial apparatus comprising a wafer carrier; wherein the wafer carrier comprises:
a first main surface suitable for receiving wafers;
a second main surface located on a side opposite to the first main surface;
an annular region concentric with the wafer carrier, which is coated with coating material having an absorption coefficient higher than that of the wafer carrier material, in the region of the second main surface; and
a resistive heater arranged on the side of the second main surface.

13. The system of claim 12, further comprising
an annular depression or an elevation containing wafer carrier material in the region of the second main surface, concentric with the wafer carrier.

14. The system of claim 12, further comprising
an annular region concentric with the wafer carrier in which material of the wafer carrier is replaced with a foreign material different from the wafer carrier material, in the region of the second main surface.

15. The system according to claim 12, wherein the heater comprises two horizontal heating coils, each having concentric windings such that the heat generated by the heater varies in a radial direction.

16. The system according to claim 12, wherein the regions coated with coating material are arranged to oppose positions of the heater having reduced heat generation.

17. The system according to claim 12, wherein a radially measured width of the depression or elevation or annular concentric region is larger than 0.5 cm.
